(19) United States
(12) Patent Application Publication
(10) Pub. No.: US 2026/0192832 A1
(43) Pub. Date: Jul. 9, 2026

(54) COLLABORATIVE METHOD FOR DISPATCHING AND TRAIN CONTROL OF FREIGHT RAILWAY

(71) Applicant: CASCO SIGNAL LTD., Shanghai (CN)

(72) Inventors: Ming XIA, Shanghai (CN); Jiao LIU, Shanghai (CN); Xiaowei HOU, Shanghai (CN); Hao LAI, Shanghai (CN); Hongjun JIANG, Shanghai (CN); Feng XUE, Shanghai (CN)

(73) Assignee: CASCO SIGNAL LTD., Shanghai (CN)

(21) Appl. No.: 19/130,564

(22) PCT Filed: Nov. 22, 2023
(86) PCT No.: PCT/CN2023/133187

§ 371 Date: May 16, 2025

(30) Foreign Application Priority Data
Sep. 11, 2023 (CN) 202311168610.8

(51) Int. Cl. B61L 27/16; B61L 27/14; B61L 27/20; B61L 27/60; G06F 30/15

(52) U.S. Cl. CPC B61L 27/16; B61L 27/14; B61L 27/20; B61L 27/60; G06F 30/15

(57) ABSTRACT

The provided is a collaborative method for dispatching and train control of a freight railway, including the following steps: performing feature extraction on basic data, dispatching command data and train operation data of a freight railway line to construct a system model; acquiring various data in a train control production system, simulating a train operation process and a dispatching command strategy in the constructed system model in conjunction with an actual transport production plan, and deducing in real time optimization solution strategies of the system model in various set scenarios; evaluating the optimization solution strategies; and applying an optimization solution strategy satisfying requirements in evaluation to the train control production system to guide actual transport production. The information barrier of a dispatching system and a train control system is broken down, thereby effectively improving the transport efficiency of the freight railway.

### CROSS-REFERENCE TO THE RELATED APPLICATIONS

This application is the national phase entry of International Application No. PCT/CN2023/133187, filed on Nov. 22, 2023, which is based upon and claims priority to Chinese Patent Application No. 202311168610.8, filed on Sep. 11, 2023, the entire contents of which are incorporated herein by reference.

### TECHNICAL FIELD

The present disclosure relates to the field of rail transit communication, and in particular, to a collaborative method and system for dispatching and train control of a freight railway.

### BACKGROUND

The daily operation of freight railways can be divided into three levels; a planning system, a dispatching system, and a control system. The planning system is responsible for compiling planned operation diagrams over a period and formulating operation plans such as train operation, locomotive operation, and construction. The dispatching system coordinates, allocates, and operates stations, sections, trains, and locomotives in a system according to the planned operation diagrams. The control system is responsible for handling routes, clearing a signal, and controlling train operation. The dispatching system and a train control system require real-time information interaction. Dispatchers send information such as operation plans, dispatching instructions, train route information, and temporary velocity restriction commands to the train control system via the dispatching system. The train control system reports routes, signals, section statuses, train positions, velocities, etc. to the dispatching system. They collaborate synergistically to complete transport tasks.

The actual network train operation environment is complex and variable. In addition to the general characteristics of common systems, it also possesses the following specificities: (1) High complexity. The freight railway train operation environment is complex, with numerous conditions and internal interference factors affecting train operation. Dispatching command and train operation rely on the dispatching and the drivers' control over environmental information and train performance, while their capabilities in handling and responding to emergencies vary by individual, leading to poor stability and uniformity in train operation. After the development of an operation control system from fixed block to moving block, the high train operation density, small intervals, strong operation coupling between trains, and poor train control effects result in significant impacts on the efficient and punctual operation of the system. For example, they can result in unplanned stops of freight trains, not only increasing additional time for starting and stopping but also increasing locomotive energy consumption. (2) High dynamism. Under the influence of internal and external factors, the freight train operation process frequently deviates from existing plans, and the dispatching and the train operation status are always in dynamic change. At present, the dispatchers cannot keep track of fine-grained train status information (e.g., velocity, position, train type, traction and braking characteristics), leading to insufficient fineness in phase adjustment plans formulated according to this. Additionally, the dispatchers have limited access to internal statuses of the train control system, such as train communication failures, and train downgrades, preventing timely and effective decision-making for solutions, hindering information collaboration between trains, lines, and networks across different layers for the dispatching and the drivers, and reducing the response velocity to emergencies. (3) High coupling. Freight railway networks are complex with multiple interference factors. Train operation exhibits strong coupling between trains, trains and lines, and lines and stations. The propagation process of train delays across the networks is complex, making it difficult for the dispatchers to adjust strategies.

The meeting of an opposing train is a critical task processed by freight railway dispatching command and train control systems. After the opposing meeting train arrives at the station, enters a track, and stops, the passing train can then pass the meeting station. To enhance the carrying capacity, the meeting process is generally tightly scheduled.

Please refer to FIG. 2 for the schematic diagram of the meeting of an opposing train. In an actual transport organization process, the train meeting requires the coordinated collaboration of personnel in multiple positions and the dispatching and train control systems: dispatching command personnel formulate a meeting plan via a centralized traffic control system (CTC system) and issue the meeting plan to a station trackside train control system to handle routes, the train control system calculates traffic authorities for trains, and an onboard system calculates velocity curves according to the authorities and line data. The plan is further communicated to drivers, who drive the trains to complete the meeting under the protection of the onboard system. Generally, the dispatchers need to repeatedly adjust the plan multiple times according to the train operation processes, the train control system must handle routes and calculate authorities multiple times, and the drivers must adjust corresponding driving strategies according to the plan and signals ahead. Poor coordination may lead to failures such as unnecessary deceleration of a passing freight train or stopping outside the signal.

Therefore, there is an urgent need to research collaborative optimization methods and technologies for dispatching command and train operation control to form an efficient, safe, and entirely new collaborative system for railway dispatching command and traffic control. Currently, there is less research on the dispatching and train collaborative optimization of the freight railways.

### SUMMARY

### Technical Problems

The present disclosure proposes a framework for achieving collaborative optimization of dispatching and train control systems of a freight railway under complex networks and time-varying environments, achieving modeling, decision-making, and optimized control thereof; and designs an improved double deep Q-network-based train target velocity curve optimization method to solve the model, where “deduction prediction” is carried out on various operation scenarios and emergencies by means of computational experiments to serve as references for actual dispatching command and train driving, and through analysis and utilization of computational simulation results, collaborative optimization of management and control is achieved.

### Technical Solutions

A collaborative method for dispatching and train control of a freight railway includes the following steps:
S1, performing feature extraction on basic data, dispatching command data and train operation data of a freight railway line to construct a system model;
S2, acquiring various data in a train control production system, simulating a train operation process and a dispatching command strategy in the constructed system model in conjunction with an actual transport production plan, and deducing in real time optimization solution strategies of the system model in various set scenarios;
S3, evaluating the optimization solution strategies; and
S4, applying an optimization solution strategy satisfying requirements in evaluation to the train control production system to guide actual transport production.

Further, the system model in step S1 includes: a basic data model, a dispatching system model, a train control system model, and a train driving model.

Further, the various data in step S2 include various emergencies in the train operation process.

Further, the optimization solution strategies in step S2 are a train velocity curve and a dispatching adjustment plan suitable for a set scenario.

Further, step S2 includes using a Q-network algorithm to set an operation environment of a passing train and a meeting train, simulating a meeting process of the passing train and the meeting train, and establishing a Markov decision process, wherein
the operation environment includes line static data, operation plans of the passing train and the meeting train, an operation position, a velocity and operation time of the passing train, and a position, a velocity and operation time of the meeting train.

Further, the meeting process is represented as an operation process of a meeting train from station k−1 to station k and an operation process of the passing train from station k+1 to station k.

Further, a section from station k−1 to station k and a section from station k+1 to station k are divided into different subsections according to a fixed velocity limit, and a maximum traction velocity and a maximum braking velocity of the meeting train or the passing train are calculated from each subsection; and
an operation velocity in a next status and an operation velocity in a previous status are calculated according to a velocity of the meeting train or the passing train in a current status, the maximum traction velocity is obtained according to the operation velocity in the next status under a premise of not exceeding a velocity limit of a corresponding subsection, the maximum braking velocity is obtained according to the operation velocity in the previous status, and the smaller of the maximum traction velocity and the maximum braking velocity is taken as a shortest operation time velocity value.

Further, time of the meeting train arriving at station k is:

$${TAr}_{k}^{m} = {TD}_{k - 1}^{m} + {\sum }_{i = 0}^{w} \frac{Δ {l}_{i}^{m}}{{\overline{v}}_{i}^{m}} ,$$

$${TD}_{k - 1}^{m}$$

being departure time of the meeting train at station k−1,

$${TAr}_{k}^{m}$$

being arrival time of the meeting train at station k,

$$Δ {l}_{i}^{m}$$

being a length of subsections of the meeting train, w being a number of subsections which the meeting train passes through, and

$${\overline{v}}_{i}^{m}$$

being a shortest operation time velocity value of the meeting train; and
time of the passing train arriving at station k is:

$${TAr}_{κ}^{n} = {TD}_{k + 1}^{n} + {\sum }_{j = 0}^{z} \frac{Δ {l}_{j}^{n}}{{\overline{v}}_{j}^{n}} , {TD}_{k + 1}^{n}$$

being departure time of the passing train at station k+1,

$${TAr}_{κ}^{n}$$

being arrival time of the passing train at station k,

$$Δ {l}_{j}^{n}$$

being a length of subsections of the passing train, z being a number of subsections which the passing train passes through, and

$${\overline{ν}}_{j}^{n}$$

being a shortest operation time velocity value of the passing train.

Further, an optimized objective function is shortest total meeting time:

$$min Δ T = {TAr}_{k}^{m} - {TAr}_{k}^{n} , and {TAr}_{k}^{m} - {TAr}_{k}^{n} > {T}_{O} ,$$

T_{O} being time for handling a route and clearing a signal for the passing train.

Further, if the meeting process is required to be smooth in operation to reduce occurrence of sudden acceleration and deceleration, an optimized objective function is a minimum acceleration change rate:

$$minSt = {\sum }_{i = 0}^{w - 1} \frac{\vert {a}_{i + 1}^{m} - {a}_{i}^{m} \vert}{{t}_{i}} \cdot Δ {l}_{i}^{m} + {\sum }_{j = 0}^{z - 1} \frac{\vert {a}_{j + 1}^{n} - {a}_{j}^{n} \vert}{{t}_{j}} \cdot Δ {l}_{j}^{n} , Δ {l}_{i}^{m} and Δ {l}_{j}^{n}$$

being a length of subsections of the meeting train and a length of subsections of the passing train, respectively,

$${a}_{i + 1}^{m}$$

being an acceleration of the meeting train at an end position of the subsections,

$${a}_{i}^{m}$$

being an acceleration of the meeting train at a start position of the subsections,

$${a}_{j + 1}^{n}$$

being an acceleration of the passing train at an end position of the subsections,

$${a}_{j}^{n}$$

being an acceleration of the passing train at a start position of the subsections, tᵢ being operation time of the meeting train within the subsections, and tⱼ being operation time of the passing train within the subsections.

Further, using a Q-network algorithm to optimize an operation process of a meeting train in step S2 includes the following steps:
S21, initializing approximation of a network parameter θ, and making an objective network parameter θ⁻ be θ;
S22, determining an operation status

$${s}_{i}^{m}$$

of the meeting train by

$$( Δ {l}_{i}^{m} , {v}_{i}^{m} , {d}^{n} , {v}_{j}^{n} , {r}_{i}^{m} ) , Δ {l}_{i}^{m}$$

being a length of subsections,

$${ν}_{i}^{m}$$

being a velocity of the meeting train, dⁿ being a distance from a passing train to a stop point,

$${v}_{j}^{n}$$

being a velocity of the passing train, and

$${r}_{i}^{m}$$

being a weighted value of an objective function; randomly selecting a condition action

$$a {c}_{i}^{m}$$

with a probability of ε, and selecting a current optimal status

$${s}_{i}^{m}$$

with a probability of 1−ε;
S23, performing the condition action

$$a {c}_{i}^{m} ,$$

and obtaining a next status

$${s}_{i + 1}^{m}$$

and a reward value

$${r}_{i + 1}^{m}$$

according to an operation environment of the meeting train;
S24, randomly drawing several

$${s}_{i}^{m} , {ac}_{i}^{m} , {r}_{i}^{m} , {s}_{i + 1}^{m}$$

from an experience replay region, and updating the network parameter θ according to a gradient descent algorithm; and
S25, updating the network parameter θ⁻ into θ through a designated number of steps, and exiting when a number of iterations is reached; otherwise, returning to S21.

The present disclosure further provides a collaborative system for dispatching and train control of a freight railway, used for implementing the collaborative method for dispatching and train control of a freight railway, including:
a perceptual learning module, configured to acquire features of basic data, dispatching command data and train operation data of a freight railway line for extraction to construct a computable and reconfigurable system model;
a collaborative optimization module, configured to acquire various data in a production system, simulate a train operation process and a dispatching command strategy in a production environment in conjunction with an actual transport production plan to deduce in real time optimization solution strategies of the system model;
a strategy evaluation module, configured to test and evaluate the optimization solution strategies generated by the collaborative optimization module; and
a strategy generation module, configured to push an optimization solution strategy satisfying a pre-defined objective to the production system for execution.

Further, the system model includes: a basic data model, a dispatching system model, a train control system model, and a train driving model.

Further, the various data is from randomly generating various emergencies.

Further, the optimization solution strategies include: a train velocity curve and a dispatching adjustment plan.

### Beneficial Effects

The information barrier of a dispatching system and a train control system is broken down, thereby effectively improving the transport efficiency of the freight railway.

A freight railway train meeting model is established, providing a detailed description of the operation processes and scheduled arrival time of a passing train and a meeting train. The model can accurately describe the collaborative process of the passing train and meeting train group during operating to a meeting station, laying the foundation for optimizing meeting operation.

A double deep Q-network-based computational method is improved by considering the velocity and position of an opposing train, which has the advantages that the velocity of the meeting train and the distance to a meeting point are considered when train curves are calculated and conditions are output, enabling collaborative control optimization of both trains' operation processes at the same time from the perspective of dispatching plans.

### BRIEF DESCRIPTION OF THE DRAWINGS

FIGS. 1A-1C show a framework of collaborative optimization of dispatching and train control of the present disclosure, where FIG. 1B shows the part 1 of FIG. 1A, and FIG. 1C shows the part 2 of FIG. 1A;

FIG. 2 shows a schematic diagram of meeting of a meeting train and a passing train;

FIG. 3 shows a process of dispatching and control for train meeting;

FIG. 4 shows a process of reinforcement learning optimization for train meeting;

FIG. 5 shows a schematic diagram of velocity curves considering train positions and velocities.

### DETAILED DESCRIPTION OF THE EMBODIMENTS

The following provides a further detailed description on the collaborative method and system for dispatching and train control proposed by the present disclosure in conjunction with the drawings and specific implementations. Based on the following description, the advantages and features of the present disclosure will be made clearer.

A collaborative system for dispatching and train control of a freight railway provided by the present disclosure comprises a perceptual learning module, a collaborative optimization module, a strategy evaluation module, and a strategy generation module. The core lies in utilizing the technological means of perceptual learning and artificial intelligence to break down the information barriers between a dispatching system and a train control system to achieve collaborative optimization of dispatching command and train operation control, dynamically feeding back the generated strategies in real time to production dispatching and train control systems to guide the train control system to control trains to operate safely, punctually, and smoothly, and assisting dispatchers in keeping track of the statuses of traffic resources such as trains, locomotives, freight trains, station routes, and sections and districts, thereby achieving unified optimized dispatching command and improving transport efficiency.

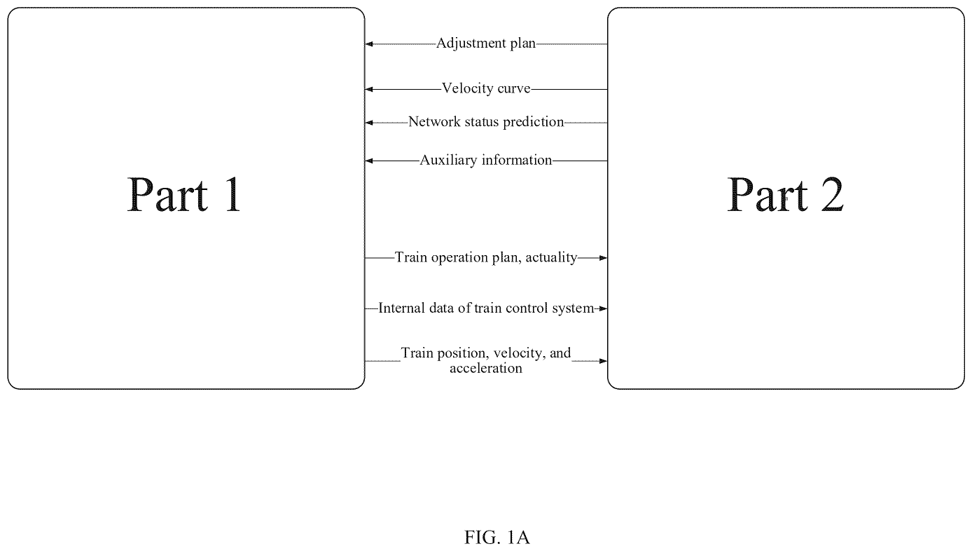

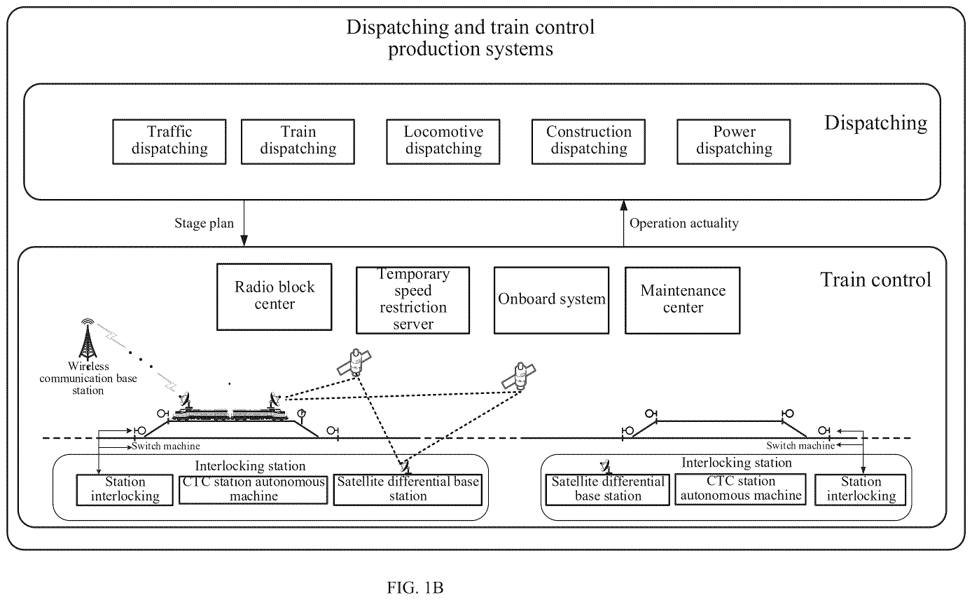

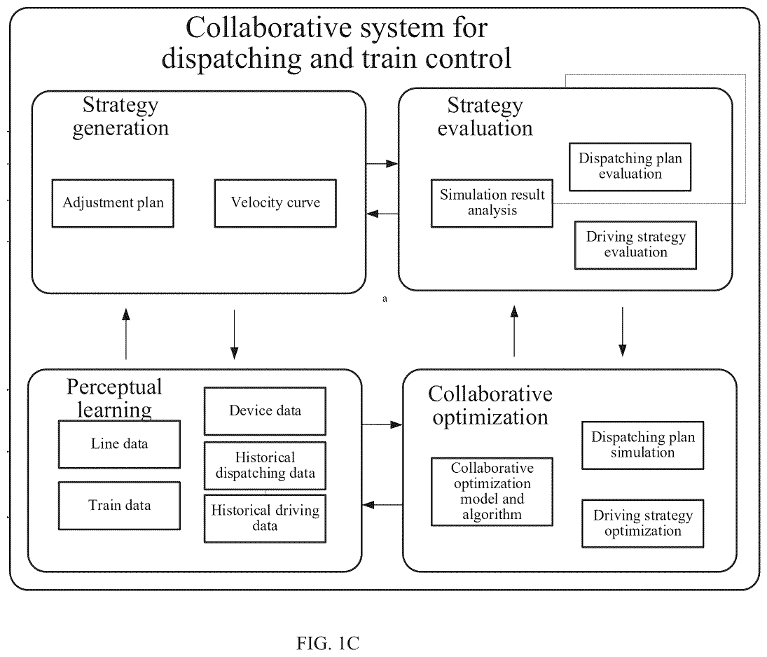

As shown in FIGS. 1A-1C, the perceptual learning module is responsible for extracting features of basic data, dispatching command data and train operation data of a freight railway line by means of knowledge engineering to construct a computable and reconfigurable system model. The system model includes a basic data model, a dispatching system model, a train control system model, a train driving model, etc.

The collaborative optimization module is responsible for using various data acquired in a production system to simulate a train operation process and a dispatching command strategy in a production environment in conjunction with an actual transport production plan to deduce in real time optimization solution strategies of the system model constructed by the perceptual learning module. The optimization solution strategies include designing daily operation scenarios for the freight railway, enabling trains to operate in a simulation environment according to given dispatching plans, randomly generating various emergencies, and automatically generating train velocity curves and dispatching strategies, thereby obtaining driving strategies applicable to the set scenarios.

The strategy evaluation module is responsible for testing and evaluating the dispatching strategies and the velocity curves generated by the collaborative optimization module around specific operation scenarios and objectives.

If the strategy evaluation module finds that a certain strategy satisfies a pre-defined objective, the strategy generation module pushes the strategy to dispatchers and drivers in the production system to guide them in transport and production.

According to the present disclosure, by constructing a collaborative system for dispatching and train control of a freight railway and utilizing simulation means, dispatching adjustment and train control experiments for complex operation scenarios are designed, status parameters under different scenarios are extracted from the actual production system, input real data is utilized for model training, and a large volume of simulated data is generated accordingly, enabling the system to continuously learn from massive data, thereby improving scenario cognition and problem-solving capabilities of the system; and the decision-making effects of dispatchers and drivers are effectively evaluated and predicted, and the learning results are not only “simulation” of actual situations but also provide an effective solution for actual production.

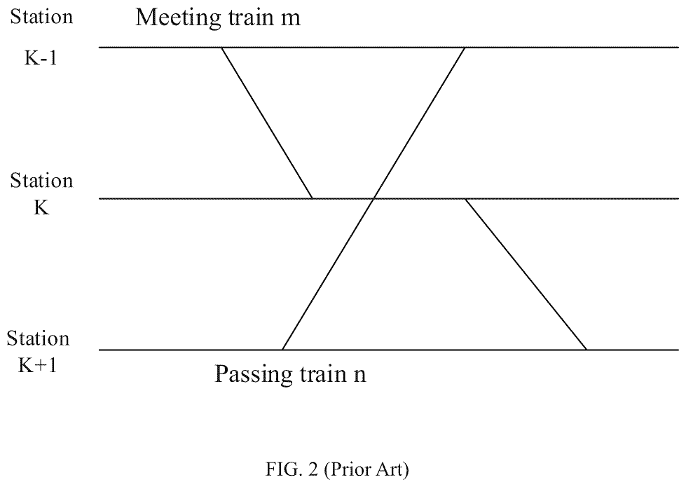

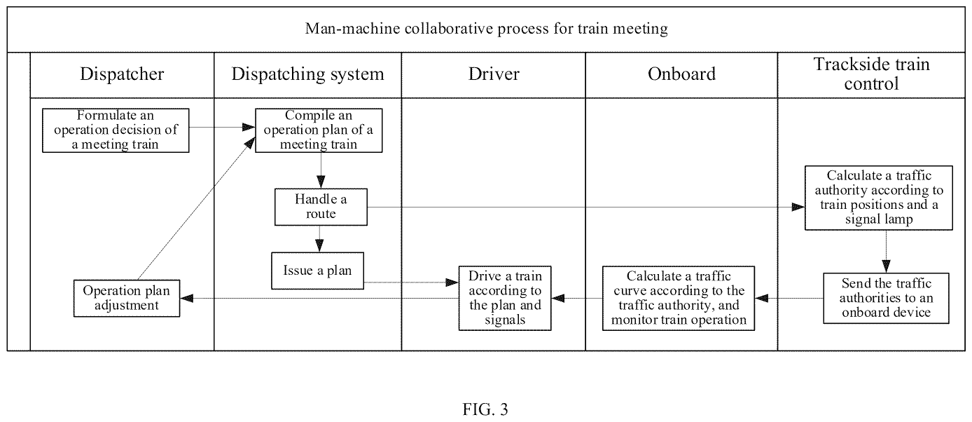

The train meeting is a critical task processed by freight railway dispatching command and train control systems. FIG. 2 shows an operation diagram of a meeting train m meeting a passing train n at station K (with a horizontal axis representing a time axis, a vertical axis representing stations, and diagonal lines representing a trains' operation process between two stations). After the meeting train m arrives at the station, enters a track, and stops, the passing train n can then pass the meeting station. To enhance the carrying capacity, the meeting process is generally tightly scheduled.

At present, the meeting of the meeting train requires the coordinated collaboration of personnel in multiple positions and the dispatching and train control systems: dispatching command personnel formulate a meeting plan via a CTC system and issue the meeting plan to a station trackside train control system to handle routes, the train control system calculates traffic authorities for trains, and an onboard system calculates velocity curves according to the authorities and line data. The plan is further communicated to drivers, who drive the trains to complete the meeting under the protection of the onboard system. Generally, the dispatchers need to repeatedly adjust the plan multiple times according to the train operation processes, the train control system must handle routes and calculate authorities multiple times, and the drivers must adjust corresponding driving strategies according to the plan and signals ahead. Poor coordination may lead to failures such as unnecessary deceleration of a passing freight train or stopping outside the signal.

To achieve the precise meeting of the two trains, the collaborative system for dispatching and train control proposed by the present disclosure constructs a unified system model for the meeting process to collaboratively control the meeting train to accelerate for entering the station and stop and the passing train to reduce the velocity for operation.

Based on the collaborative system for dispatching and train control proposed above, a collaborative method for dispatching and train control of a freight railway of the present disclosure includes the following steps:
S1, performing feature extraction on basic data, dispatching command data and train operation data of a freight railway line to construct a system model;
S2, acquiring various data in a train control production system, simulating a train operation process and a dispatching command strategy in the constructed system model in conjunction with an actual transport production plan, and deducing in real time optimization solution strategies of the system model in various set scenarios;
S3, evaluating the optimization solution strategies; and
S4, applying an optimization solution strategy satisfying requirements in evaluation to the train control production system to guide actual transport production.

Further, step S2 includes using a Q-network algorithm to set an operation environment of a passing train and a meeting train, simulating a meeting process of the passing train and the meeting train, and establishing a Markov decision process, wherein the operation environment includes line static data, operation plans of the passing train and the meeting train, an operation position, a velocity and operation time of the passing train, and a position, a velocity and operation time of the meeting train.

The meeting process is represented as an operation process of a meeting train from station k−1 to station k and an operation process of the passing train from station k+1 to station k.

The operation process of the meeting train m in a section is taken as an example for illustration.

$${TD}_{k - 1}^{m}$$

represents departure time of the train at station k−1, and

$${TAr}_{k}^{m}$$

represents arrival time of the train at station k. A section line from station k−1 to station k is divided into different subsections according to a fixed velocity limit. Each subsection has a start position

$${l}_{i}^{m} ,$$

an end position

$${l}_{i + 1}^{m} ,$$

and a velocity limit value

$${V}_{i}^{m}$$

of the subsection. A maximum traction velocity of the train is calculated from the start position

$${l}_{i}^{m}$$

of each subsection. An operation velocity

$${v}_{i + 1}^{m}$$

in a next status is calculated according to a velocity

$${v}_{i}^{m}$$

of the train in a current status. If

$${v}_{i + 1}^{m} > {V}_{i + 1}^{m} ,$$

the operation velocity in the next status is a velocity limit value

$${V}_{i + 1}^{m}$$

of a corresponding subsection, otherwise, it is the calculated operation velocity

$${v}_{i + 1}^{m} ,$$

finally obtaining the maximum traction velocity

$${vt}_{i}^{m} .$$

A maximum braking velocity of the train is calculated forward from the start position

$${l}_{i}^{m}$$

of each subsection. An operation velocity

$${v}_{i - 1}^{m}$$

in a previous status is calculated according to the velocity

$${v}_{i}^{m}$$

of the train in a current status. If

$${v}_{i - 1}^{m} > {V}_{i - 1}^{m} ,$$

the operation velocity in the previous status is a velocity limit value

$${V}_{i - 1}^{m}$$

of a corresponding subsection, finally obtaining the maximum braking velocity

$${vb}_{i}^{m} \cdot {vt}_{i}^{m} and {vb}_{i}^{m}$$

are compared, from which the smaller is selected, i.e.,

$${\overline{v}}_{i}^{m} = min ( {vt}_{i}^{m} , {vb}_{i}^{m} ) ,$$

thereby obtaining a shortest operation time velocity value

$${\overline{v}}_{i}^{m} .$$

The time of the meeting train arriving at station k is:

$${TAr}_{k}^{m} = {TD}_{k - 1}^{m} + {\sum }_{i = 0}^{w} \frac{Δ {l}_{i}^{m}}{{\overline{v}}_{i}^{m}} ,$$

w being the number of subsections. A maximum traction velocity of the train at the end position

$${l}_{i + 1}^{m}$$

of the subsection is:

$${v}_{i + 1}^{m} = \sqrt{2 {a}_{i + 1}^{m} Δ l + {v}_{i}^{{m}^{2}}} , with {v}_{i}^{m} = \sqrt{{v}_{i + 1}^{{m}^{2}} - 2 {a}_{i + 1}^{m} Δ l}$$

when a braking velocity is calculated. A resultant force acting on the train is:

$${F}_{all}^{m} = {p}_{t} * {F}_{t} ( i ) - {p}_{b} * {F}_{b} ( i ) - {f}_{b} ( i ) - {f}_{a} ( i ) ,$$

Fₜ being a traction force, pₜ being a traction force coefficient, p_{b} being a braking force coefficient, F_{b} being a braking force, f_{b} being a basic resistance, and fₐ being an additional resistance. Train acceleration:

$${a}_{i + 1}^{m} = \frac{{F}_{all}^{m}}{{M}^{m}} ,$$

M^{m} being a mass of the meeting train. A velocity of the meeting train is in a range:

$$0 \leq {v}_{i}^{m} \leq \overline{{v}_{i}^{m}} .$$

Similarly, a process model for the passing train n in the section from station K+1 to station k can be established. The difference between the two lies in that the meeting train needs to stop at the meeting station according to the plan, hence its final velocity is:

$${v}_{s}^{m} = 0 ,$$

and the final velocity of the passing train is:

$${v}_{s}^{n} > 0.$$

Generally, the departure time of the meeting train m at station k−1 and the departure time of the passing train n at station k+1 is already determined. The objective function to be optimized is the shortest total meeting time:

$$min Δ T = {TAr}_{k}^{m} - {TAr}_{k}^{n} . {TAr}_{k}^{n}$$

represents the time of the passing train arriving at station k. However, the meeting time must satisfy the time T_{O} for handling a route and clearing a signal for the passing train, and

$${TAr}_{k}^{m} - TA {r}_{k}^{n} > {T}_{O} .$$

It is hoped that the train operates smoothly to reduce occurrence of sudden acceleration and deceleration, i.e., a minimum acceleration change rate:

$$min St + {\sum }_{i = 0}^{w - 1} \frac{\vert {a}_{i + 1}^{m} - {a}_{i}^{m} \vert}{{t}_{i}} \cdot Δ {l}_{i}^{m} + {\sum }_{j = 0}^{z - 1} \frac{\vert {a}_{j + 1}^{m} - {a}_{j}^{m} \vert}{{t}_{j}} , Δ {l}_{j}^{n} , Δ {l}_{i}^{m} and Δ {l}_{j}^{n}$$

being a length of subsections of the meeting train m and a length of subsections of the passing train n respectively,

$${a}_{i + 1}^{m}$$

being an acceleration of the meeting train m at an end position

$${l}_{i + 1}^{m}$$

of the subsections thereof,

$${a}_{i}^{m}$$

being an acceleration of the meeting train m at a start position

$${l}_{i}^{m}$$

of the subsections thereof,

$${a}_{j + 1}^{n}$$

being an acceleration of the passing train n at an end position

$${l}_{j + 1}^{n}$$

of the subsections thereof,

$${a}_{j}^{n}$$

being an acceleration of the passing train at a start position

$${l}_{j}^{n}$$

of the subsections, tᵢ being operation time of the meeting train m within the subsections thereof, and tⱼ being operation time of the passing train within the subsections thereof.

Further, a Q-network reinforcement learning environment can be set as an actual train operation environment, including line static data, train operation plans, an operation position, a velocity and operation time of a passing train, and a position, a velocity and operation time of an opposing meeting train. A Markov decision process MDP=<S, AC, P, R> is established, where S, A, P, R represent a set of operation statuses of a meeting train group, output operation conditions of the meeting train group, a status transition probability, and a reward, respectively. The magnitude of the reward value is determined by the total meeting time and the driving smoothness. The collaborative process is illustrated using a meeting train as an example.

$${r}_{i}^{m}$$

is a weighted average of two objective functions: the shortest total meeting time and the minimum acceleration change rate, i.e., w₁·ΔT+w₂·St, w₁, w₂ being coefficients of the two objectives. The benefits of the train operation status including an opposing train lie in that the velocity of the meeting train and the distance to a meeting point are considered when train curves are calculated and conditions are output, enabling collaborative control optimization of both trains' operation processes at the same time from the perspective of dispatching plans. The optimization method for operation of the meeting train m in a section is as follows:
S21, initializing approximation of a network parameter θ, and making an objective network parameter θ⁻ be θ;
S22, determining an operation status

$${s}_{i}^{m}$$

of the meeting train by

$$( Δ {l}_{i}^{m} , {v}_{i}^{m} , {d}^{n} , {v}_{j}^{n} , {r}_{i}^{m} ) , Δ {l}_{i}^{m}$$

being a length of subsections,

$${v}_{i}^{m}$$

being a velocity of the meeting train, dⁿ being a distance from a passing train to a stop point,

$${v}_{j}^{n}$$

being a velocity of the passing train, and

$${r}_{i}^{m}$$

being a weighted value of an objective function; randomly selecting a condition action

$${ac}_{i}^{m}$$

with a probability of ε, and selecting a current optimal status

$${s}_{i}^{m}$$

with a probability of 1−ε;
S23, performing the condition action

$$a {c}_{i}^{m} ,$$

and obtaining a next status

$${s}_{i + 1}^{m}$$

and a reward value

$${r}_{i + 1}^{m}$$

according to an operation environment of the meeting train;
S24, randomly drawing several

$${s}_{i}^{m} , {ac}_{i}^{m} , {r}_{i}^{m} , {s}_{i + 1}^{m}$$

from an experience replay region, and updating the network parameter θ according to a gradient descent algorithm; and
S25, updating the network parameter θ⁻ into θ through a designated number of steps, and exiting when a number of iterations is reached; otherwise, returning to S21.

Onboard agents of the meeting train and the passing train continuously interact with the reinforcement learning environment according to the above optimization process. The onboard agents calculate the train operation condition actions in the current state according to the positions, velocities, and operation time of the trains, enabling both the meeting train and the passing train to tend to the shortest meeting time and smooth operation.

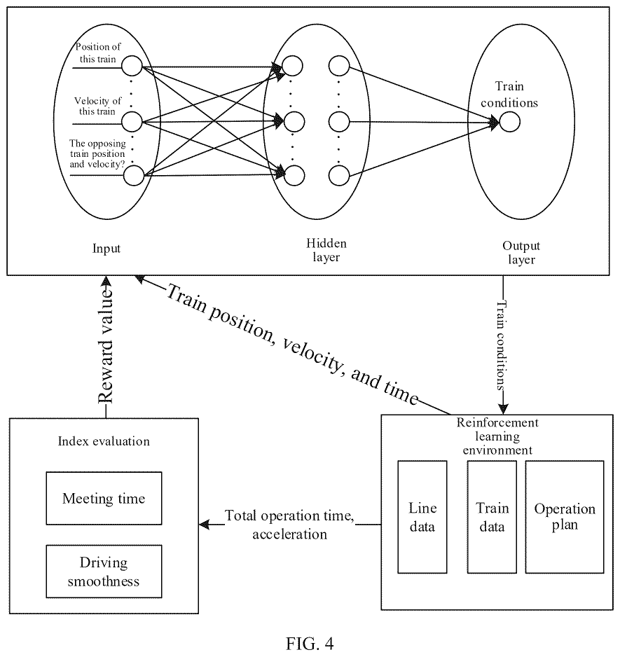

The train operation environment calculates train acceleration sequences and the time of the train arriving at station k for the condition actions of the onboard agents of the meeting train and the passing train, and generates new train operation statuses, reward values, and action value functions. The two agents select the maximum action value function and feed it back to the reinforcement learning environment. The agents utilize the closed-loop structure to continuously update the conditions, ultimately obtaining an optimal condition action sequence. The velocity curve corresponding to the condition action sequence is an optimal velocity curve, as shown in FIG. 4.

Taking the data of a local railway line as an example, the section from station JK to station MP is 6.6 km long with operation time of 15 minutes, and the section from station MP to station BF is 10.8 km long with operation time of 20 minutes. The direction of JK->MP->BF is a loaded train direction. The direction of BF->MP->JK is an empty train direction. The locomotive is a DF7G, hauling a 26-car consist with a total train mass of 2,500 tons and a maximum traction force of 270 KN. The passing train has an initial velocity of 0 km/h and a final velocity of 70 km/h, passing through station MP via a main track. The meeting train has an initial velocity of 0 km/h and a final velocity of 0 km/h, finally stopping at a siding track of station MP. The test line data are shown in Table 1 and Table 2.

TABLE 1
Line conditions of test section 1

| District No. | 1 | 2 | 3 | 4 | 5 | 6 | 7 | 8 | 9 | 10 | 11 |
|---|---|---|---|---|---|---|---|---|---|---|---|
| Length (m) | 406 | 390 | 860 | 510 | 260 | 430 | 270 | 310 | 450 | 760 | 800 |
| Slope (‰) | −0.40 | 2.00 | 9.50 | −10.30 | −5.80 | −3.60 | 0.50 | 7.00 | 3.70 | 0.20 | 3.30 |
| Velocity | 30 | 30 | 50 | 50 | 50 | 50 | 50 | 50 | 50 | 70 | 70 |
| limit (km/h) | | | | | | | | | | | |

TABLE 2
Line conditions of test section 2

| District No. | 1 | 2 | 3 | 4 | 5 | 6 | 7 | 8 | 9 | 10 | 11 | 12 | 13 |
|---|---|---|---|---|---|---|---|---|---|---|---|---|---|
| Length (m) | 800 | 340 | 210 | 1,100 | 260 | 720 | 460 | 1,660 | 1,840 | 980 | 650 | 1,700 | 800 |
| Slope (‰) | −4.00 | −7.30 | 3.60 | 11.10 | 5.90 | 3.00 | 1.00 | 5.20 | 3.60 | 5.30 | 3.50 | 0.80 | 3.30 |
| Velocity | 50 | 50 | 50 | 50 | 50 | 50 | 50 | 50 | 50 | 50 | 50 | 50 | 50 |
| limit (km/h) | | | | | | | | | | | | | |

The target network has fixed update steps of 300, the experience replay buffer capacity is 10,000, the batch size for each experience replay is 64, the deep learning rate is α=0.02, the discount factor is γ=0.8, the initial epsilon is ε=0.9, the final epsilon is ε=0.08, and for each status transition, Δϑ=6×10⁻⁶.

With the shortest meeting time and driving smoothness as optimization objectives, the collaborative optimization of train group dispatching plans and operation control is achieved. Information related to train operation is collected, and feasible optimized velocity-position curves are generated in conjunction with actual operation diagrams, section basic conditions, and train basic parameters. The ultimate goal of collaborative optimization between train operation time and velocity curves is to minimize the weighted sum of train delay time and smoothness. The core strategy lies in continuously adjusting the operation time of trains in each section and deriving the optimal velocity curve under the operation time, feeding back a set of operation time and acceleration into a train operation time adjustment model, and finally obtaining an optimal operation time adjustment strategy.

Generally, when the meeting of an opposing train is not considered, the passing train generates a velocity curve with a maximum velocity as an objective. During the simulation experiments, considering the situation where the opposing train fails to reach the target velocity for operation during entering the station due to certain reasons resulting in arrival time delay, the passing train continuously adjusts its velocity in each section to ensure its arrival time precisely satisfies the meeting interval time, thereby avoiding the situations such as stopping outside the signal. Table 3 describes the corresponding positions and velocities optimized by the passing train according to information such as the position and velocity of the meeting train during optimization.

TABLE 3
Table for velocity strategies of
a passing train considering an opposing train

| | Remaining | Velocity | Arrival | | Maximum |
|---|---|---|---|---|---|
| | distance of | of | remaining | Remaining | velocity |
| | opposing | opposing | time of | distance | of this |
| | train | train | opposing | of this | train |
| No. | (m) | (km/h) | train (s) | train (m) | (km/h) |
| 1 | 1,550 | 50 | 239.7 | 1,600 | 48 |
| 2 | 1,550 | 40 | 295.5 | 1,600 | 38 |
| 3 | 1,550 | 30 | 388.5 | 1,600 | 29 |
| 4 | 1,550 | 20 | 574.5 | 1,600 | 20 |
| 5 | 1,370 | 50 | 213.78 | 1,370 | 46 |
| 6 | 1,370 | 40 | 263.1 | 1,370 | 37 |
| 7 | 1,370 | 30 | 345.3 | 1,370 | 28 |
| 8 | 1,370 | 20 | 509.7 | 1,370 | 19 |
| 9 | 600 | 30 | 160.5 | 600 | 26 |
| 10 | 600 | 20 | 232.5 | 600 | 18 |

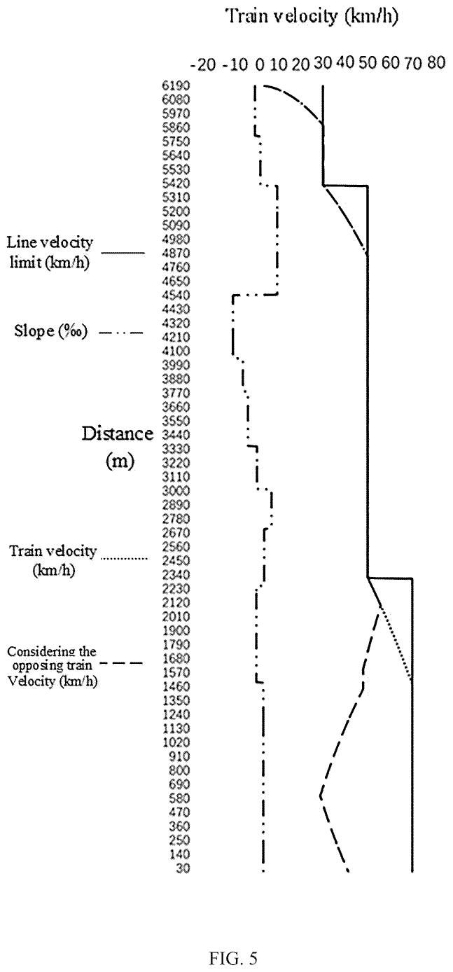

During simulation, the velocity curves generated for the passing train considering the position and velocity of the opposing train are shown in FIG. 5. The passing train reduces the velocity in advance according to the position of the meeting train at approximately two kilometers from the station. After the meeting train enters the station, the passing train increases the velocity and passes through the station quickly.

Therefore, by adopting the above method, when the passing train approaches station MP, the passing train can be automatically controlled to reduce the velocity in advance according to the positions and velocities of the two trains, and the meeting train accelerates to enter the station, thereby improving the meeting efficiency of the two trains. On the one hand, the passing train can be effectively prevented from stopping outside the signal due to waiting for the meeting train to enter the station. On the other hand, the frequent communication costs between the dispatchers and the drivers of the two trains during meeting are reduced.

Compared with the prior art, the present disclosure has the following beneficial effects:
1. The information barrier of a dispatching system and a train control system is broken down, thereby effectively improving the transport efficiency of the freight railway.
2. A freight railway train meeting model is established, providing a detailed description of the operation processes and scheduled arrival time of a passing train and a meeting train. The model can accurately describe the collaborative process of the passing train and meeting train group during operating to a meeting station, laying the foundation for optimizing meeting operation.
3. A double deep Q-network-based computational method is improved by considering the velocity and position of an opposing train, which has the advantages that the velocity of the meeting train and the distance to a meeting point are considered when train curves are calculated and conditions are output, enabling collaborative control optimization of both trains' operation processes at the same time from the perspective of dispatching plans.

Although the content of the present disclosure has been described in detail through the above preferred embodiments, it should be understood that the above description should not be considered as limiting the present disclosure. After reading the above content, various modifications and alternatives to the present disclosure will be apparent to those skilled in the art. Therefore, the scope of protection of the present disclosure should be defined by the appended claims.

What is claimed is:

1. A collaborative method for dispatching and train control of a freight railway, comprising:
S1, performing feature extraction on basic data, dispatching command data and train operation data of a freight railway line to construct a system model;
S2, acquiring various data in a train control production system, simulating a train operation process and a dispatching command strategy in the system model in conjunction with an actual transport production plan, and deducing in real time optimization solution strategies of the system model in various set scenarios;
S3, evaluating the optimization solution strategies; and
S4, applying an optimization solution strategy satisfying requirements in evaluation to the train control production system to guide actual transport production.

2. The collaborative method according to claim 1, wherein the system model in step S1 comprises: a basic data model, a dispatching system model, a train control system model, and a train driving model.

3. The collaborative method according to claim 1, wherein the various data in step S2 comprise various emergencies in the train operation process.

4. The collaborative method according to claim 1, wherein the optimization solution strategies in step S2 are a train velocity curve and a dispatching adjustment plan suitable for a set scenario.

5. The collaborative method according to claim 1, wherein step S2 comprises using a Q-network algorithm to set an operation environment of a passing train and a meeting train, simulating a meeting process of the passing train and the meeting train, and establishing a Markov decision process, wherein
the operation environment comprises line static data, operation plans of the passing train and the meeting train, an operation position, a velocity and operation time of the passing train, and a position, a velocity and operation time of the meeting train.

6. The collaborative method according to claim 5, wherein the meeting process is represented as an operation process of a meeting train from station k−1 to station k and an operation process of the passing train from station k+1 to station k.

7. The collaborative method according to claim 6, wherein a section from station k−1 to station k and a section from station k+1 to station k are divided into different subsections according to a fixed velocity limit, and a maximum traction velocity and a maximum braking velocity of the meeting train or the passing train are calculated from each subsection; and
an operation velocity in a next status and an operation velocity in a previous status are calculated according to a velocity of the meeting train or the passing train in a current status, the maximum traction velocity is obtained according to the operation velocity in the next status under a premise of not exceeding a velocity limit of a corresponding subsection, the maximum braking velocity is obtained according to the operation velocity in the previous status, and the smaller of the maximum traction velocity and the maximum braking velocity is taken as a shortest operation time velocity value.

8. The collaborative method according to claim 7, wherein
time of the meeting train arriving at station k is:
$${TAr}_{k}^{m} = {TD}_{k - 1}^{m} + {\sum }_{i = 0}^{w} \frac{Δ {l}_{i}^{m}}{{\overline{v}}_{i}^{m}} , {TD}_{k - 1}^{m}$$
being departure time of the meeting train at station k−1,
$${TAr}_{k}^{m}$$
being arrival time of the meeting train at station k,
$$Δ {l}_{i}^{m}$$
being a length of subsections of the meeting train, w being a number of subsections which the meeting train passes through, and
$${\overline{v}}_{i}^{m}$$
being a shortest operation time velocity value of the meeting train; and
time of the passing train arriving at station k is:
$${TAr}_{κ}^{n} = {TD}_{k + 1}^{n} + {\sum }_{j = 0}^{z} \frac{Δ {l}_{j}^{n}}{{\overline{v}}_{j}^{n}} , T {D}_{k + 1}^{n}$$
being departure time of the passing train at station k+1,
$${TAr}_{k}^{n}$$
being arrival time of the passing train at station k,
$$Δ {l}_{j}^{n}$$
being a length of subsections of the passing train, z being a number of subsections which the passing train passes through, and
$${\overline{v}}_{j}^{n}$$
being a shortest operation time velocity value of the passing train.

9. The collaborative method according to claim 8, wherein an optimized objective function is shortest total meeting time:
$$min Δ T = T A {r}_{k}^{m} - T A {r}_{k}^{n} , and {TAr}_{k}^{m} - {TAr}_{k}^{n} > {T}_{O} ,$$
T_{O} being time for handling a route and clearing a signal for the passing train.

10. The collaborative method according to claim 8, wherein
when the meeting process is required to be smooth in operation to reduce occurrence of sudden acceleration and deceleration, an optimized objective function is a minimum acceleration change rate:
$$min St = {\sum }_{i = 0}^{w - 1} \frac{\vert {a}_{i + 1}^{m} - {a}_{i}^{m} \vert}{{t}_{i}} \cdot Δ {l}_{i}^{m} + {\sum }_{j = 0}^{z - 1} \frac{\vert {a}_{j + 1}^{n} - {a}_{j}^{n} \vert}{{t}_{j}} \cdot Δ {l}_{j}^{n} , Δ {l}_{i}^{m} and$$
$$Δ {l}_{j}^{n}$$
being a length of subsections of the meeting train and a length of subsections of the passing train, respectively,
$${a}_{i + 1}^{m}$$
being an acceleration of the meeting train at an end position of the subsections,
$${a}_{i}^{m}$$
being an acceleration of the meeting train at a start position of the subsections,
$${a}_{j + 1}^{n}$$
being an acceleration of the passing train at an end position of the subsections,
$${a}_{j}^{n}$$
being an acceleration of the passing train at a start position of the subsections, tᵢ being operation time of the meeting train within the subsections, and tⱼ being operation time of the passing train within the subsections.

11. The collaborative method according to claim 1, wherein using a Q-network algorithm to optimize an operation process of a meeting train in step S2 comprises the following steps:
S21, initializing approximation of a network parameter θ, and making an objective network parameter θ⁻ be θ;
S22, determining an operation status
$${s}_{i}^{m}$$
of the meeting train by
$$( Δ {l}_{i}^{m} , {v}_{i}^{m} , {d}^{n} , {v}_{j}^{n} , {r}_{i}^{m} ) ,$$
$$Δ {l}_{i}^{m}$$
being a length of subsections,
$${ν}_{i}^{m}$$
being a velocity of the meeting train, dⁿ being a distance from a passing train to a stop point,
$${v}_{j}^{n}$$
being a velocity of the passing train, and
$${r}_{i}^{m}$$
being a weighted value of an objective function; randomly selecting a condition action
$${ac}_{i}^{m}$$
with a probability of ε, and selecting a current optimal status
$${s}_{i}^{m}$$
with a probability of 1−ε;
S23, performing the condition action
$$a {c}_{i}^{m} ,$$
and obtaining a next status
$${s}_{i + 1}^{m}$$
and a reward value
$${r}_{i + 1}^{m}$$
according to an operation environment of the meeting train;
S24, randomly drawing several
$${s}_{i}^{m} , {ac}_{i}^{m} , {r}_{i}^{m} , {s}_{i + 1}^{m}$$
from an experience replay region, and updating the network parameter θ according to a gradient descent algorithm; and
S25, updating the network parameter θ⁻ into θ through a designated number of steps, and exiting when a number of iterations is reached; when the number of iterations is not reached, returning to S21.

12. A collaborative system for dispatching and train control of a freight railway, configured for implementing the collaborative method according to claim 1, comprising:
a perceptual learning module, configured to acquire features of the basic data, the dispatching command data and the train operation data of the freight railway line for extraction to construct a computable and reconfigurable system model;
a collaborative optimization module, configured to acquire the various data in the train control production system, simulate the train operation process and the dispatching command strategy in a production environment in conjunction with the actual transport production plan to deduce in real time the optimization solution strategies of the system model;
a strategy evaluation module, configured to test and evaluate the optimization solution strategies generated by the collaborative optimization module; and
a strategy generation module, configured to push an optimization solution strategy satisfying a pre-defined objective to the production system for execution.

13. The collaborative system according to claim 12, wherein the system model comprises: a basic data model, a dispatching system model, a train control system model, and a train driving model.

14. The collaborative system according to claim 12, wherein the various data is from randomly generating various emergencies.

15. The collaborative system according to claim 12, wherein the optimization solution strategies comprise: a train velocity curve and a dispatching adjustment plan.
